(19) United States
(12) Patent Application Publication
(10) Pub. No.: US 2018/0226292 A1
(43) Pub. Date: Aug. 9, 2018

(54) TRENCH ISOLATION FORMATION FROM THE SUBSTRATE BACK SIDE USING LAYER TRANSFER

(71) Applicant: GLOBALFOUNDRIES Inc., Grand Cayman (KY)

(72) Inventors: John J. Pekarik, Underhill, VT (US); Anthony K. Stamper, Williston, VT (US); Vibhor Jain, Essex Junction, VT (US)

(21) Appl. No.: 15/425,384

(22) Filed: Feb. 6, 2017

(51) Int. Cl. H01L 21/762; H01L 27/12

(52) U.S. Cl. CPC H01L 21/76289; H01L 29/78; H01L 27/1203; H01L 21/76283

(57) ABSTRACT

Structures with trench isolation and methods for making a structure with trench isolation. A transistor is formed by front-end-of-line processing on a first surface of a semiconductor substrate. A barrier layer is formed by middle-of-line processing on the transistor and the first surface of the semiconductor substrate. After the transistor and the barrier layer are formed, a trench is etched into the semiconductor substrate from a second surface of the semiconductor substrate that is opposite from the first surface of the semiconductor substrate. The trench, which is used to form an isolation region, may terminate on a dielectric layer associated with the transistor or may terminate on the barrier layer.

### BACKGROUND

The present invention relates to semiconductor device fabrication and integrated circuits and, more specifically, to structures with trench isolation and methods for making a structure with trench isolation.

Complementary-metal-oxide-semiconductor (CMOS) processes may be used to build a combination of p-type field-effect transistors (pFETs) and n-type field-effect transistors (nFETs) that are coupled to implement logic gates and other types of integrated circuits, such as switches. Field-effect transistors generally include a device body, a source, a drain, and a gate electrode associated with a channel that is formed in the device body. When a control voltage exceeding a designated threshold voltage is applied to the gate electrode, carrier flow occurs in an inversion or depletion layer as the channel in the device body between the source and drain to produce a device output current.

Bipolar junction transistors are three-terminal electronic devices that include an emitter, a collector, and an intrinsic base arranged between the emitter and collector. A heterojunction bipolar transistor is a type of bipolar junction transistor in which two or more of the emitter, intrinsic base, and/or collector are composed of semiconductor materials with unequal band gaps, which creates heterojunctions instead of homojunctions. For example, the collector and/or emitter of a heterojunction bipolar transistor may be composed of silicon, and the base of a heterojunction bipolar transistor may be composed of a narrower band gap material, such as silicon silicon-germanium. In operation, the base-emitter junction is forward biased and the base-collector junction is reverse biased. The collector-emitter current may be controlled by the base-emitter voltage.

Active regions for building transistors may be defined using trench isolation. The trench isolation process generally includes etching a pattern of trenches in the semiconductor substrate, filling the trenches with one or more dielectric layers, and removing the excess dielectric material using chemical-mechanical planarization. The resultant isolation structures formed in the trenches provide electrical isolation between different active regions in which devices, such as field-effect transistors or bipolar junction transistors, are formed.

Improved structures with trench isolation and methods for making a structure with trench isolation are needed.

### SUMMARY

In an embodiment of the invention, a method includes forming, by front-end-of-line processing, a transistor on a first surface of a semiconductor substrate. The method further includes forming a barrier layer on the transistor and the first surface of the semiconductor substrate. After the transistor and the barrier layer are formed, a trench is etched from a second surface of the semiconductor substrate that is opposite from the first surface of the semiconductor substrate. The trench, which is used to form an isolation region, may terminate on a dielectric layer associated with the transistor or may terminate on the barrier layer.

In an embodiment of the invention, a structure includes a semiconductor substrate having a first surface and a second surface that is opposite from the first surface of the substrate, and a transistor on the first surface of a semiconductor substrate. The transistor includes a dielectric layer. A barrier layer is located on the transistor and the first surface of the semiconductor substrate. An isolation region includes a trench extending from the second surface of the semiconductor substrate through the semiconductor substrate to terminate on the dielectric layer of the transistor or on the barrier layer

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-5 are cross-sectional views of a substrate at successive stages of a processing method in accordance with embodiments of the invention.

FIGS. 6-7 are cross-sectional views of a substrate at successive stages of a processing method in accordance with embodiments of the invention.

FIG. 8 is a cross-sectional view of a substrate at a stage of a processing method in accordance with embodiments of the invention.

### DETAILED DESCRIPTION

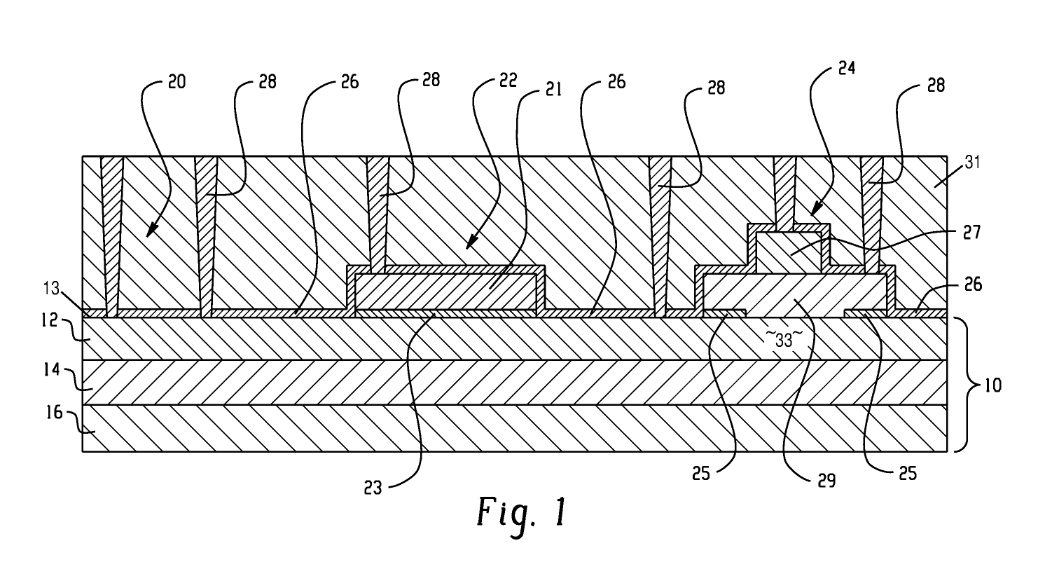

With reference to FIG. 1 and in accordance with embodiments of the invention, a semiconductor substrate 10 may be a semiconductor-on-insulator (SOI) substrate that includes a device layer 12, a buried oxide (BOX) layer 14, and a handle wafer 16. The device layer 12 is separated from the handle wafer 16 by the intervening BOX layer 14 and is considerably thinner than the handle wafer 16. The device layer 12 is located on a top surface of the BOX layer 14 and is electrically insulated from the handle wafer 16 by the BOX layer 14. The BOX layer 14 may be comprised of an electrical insulator, such as silicon dioxide (e.g., SiO₂).

Device structures 20, 22, 24 are formed at and on a front side surface 13 of the device layer 12 of the semiconductor substrate 10 by FEOL processing. The device structure 20 may be a passive device, which may have the representative form of a resistor. The device structure 22 may be a field-effect transistor that includes a gate electrode 21 and a gate dielectric layer 23 comprised of an electrical insulator, such as silicon dioxide (SiO₂), deposited by chemical vapor deposition (CVD). The device structure 22 may include additional features that are characteristic of a field-effect transistor. The device structure 24 may be a bipolar junction transistor or a heterojunction bipolar transistor that includes a base dielectric layer 25 comprised of a dielectric material, such as silicon dioxide (SiO₂), deposited by CVD. The base dielectric layer 25 may function as a protect layer to cover the device structure 22 during the fabrication of device structure 24. The device structure 24 may include an emitter 27, a base 29, and a collector 33 in the device layer 12 with a structural arrangement that is characteristic of a bipolar junction transistor or a heterojunction bipolar transistor. The device structure 24 may include additional features that are characteristic of a bipolar junction transistor or a heterojunction bipolar transistor.

A barrier layer 26 may be deposited that follows the contours of the surfaces of the device structures 20, 22, 24. The barrier layer 26 may be composed of a dielectric material, such as silicon nitride (Si₃N₄), deposited by CVD. An interlayer dielectric layer 31, such as an electrical insulator like silicon dioxide (SiO₂), may be deposited by CVD and planarized using chemical mechanical polishing (CMP). Contacts 28 may be formed in the interlayer dielectric layer 31 by middle-of-line (MOL) processing to provide a local interconnect structure. The contacts 28, which may be comprised of tungsten (W), penetrate through the barrier layer 26 for connection with portions of the device structures 20, 22, 24.

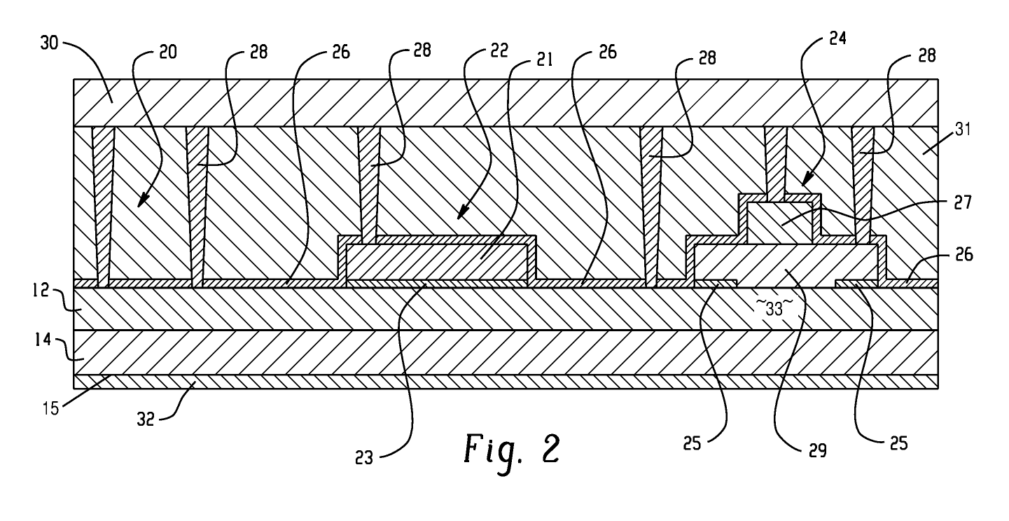

With reference to FIG. 2 in which like reference numerals refer to like features in FIG. 1 and at a subsequent fabrication stage, a temporary handle wafer 30 is bonded to the interlayer dielectric layer 31. The handle wafer 16 of the semiconductor substrate 10 is completely removed by grinding, polishing, and/etching to expose a back side surface 15 of the semiconductor substrate 10, which is disposed on the BOX layer 14 after removal of the handle wafer 16. The back side surface 15 is opposite to the front side surface 13. A dielectric layer 32, which may be comprised of silicon nitride (Si₃N₄), is deposited on the exposed back side surface 15 of the BOX layer 14.

A resist layer 34 is formed on the dielectric layer 32 and patterned. Specifically, the resist layer 34 may be composed of an organic photoresist that is applied by spin-coating, pre-baked, exposed to a pattern of radiation from an exposure source projected through a photomask, baked after exposure, and developed with a chemical developer to form openings situated at the intended locations at which trenches are to be formed, as described hereinafter.

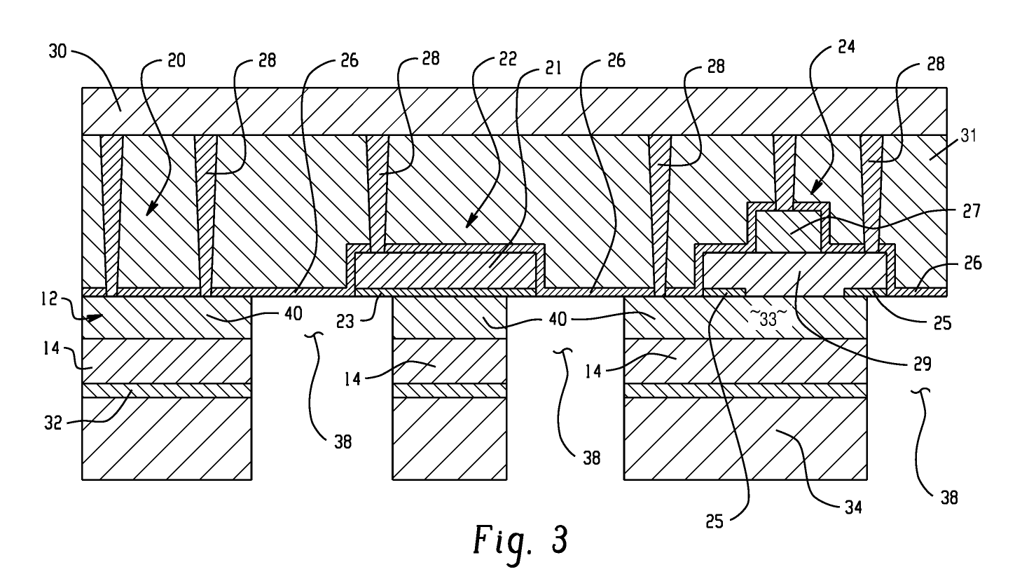

With reference to FIG. 3 in which like reference numerals refer to like features in FIG. 2 and at a subsequent fabrication stage, trenches 38 are etched that that extend from the back side surface 15 through the dielectric layer 32, the BOX layer 14, and the device layer 12. Sections 40 of the device layer 12 are located between the trenches 38 and may define respective active regions for the device structures 22, 24. The patterned resist layer 34 is used as an etch mask for an etching process, such as reactive-ion etching (RIE), that removes unmasked portions of the dielectric layer 32, the BOX layer 14, and the device layer 12 at the locations of the openings in the patterned resist layer 34 to form the trenches 38. The etching process may be conducted in a single etching step with a given etch chemistry or in multiple etching steps with different etch chemistries. The resist layer 34 is stripped after the trenches 38 are etched.

The etching process removing the device layer 12 is selected to remove the device layer 12 selective to dielectric materials and, in particular to the gate dielectric layer 23, the base dielectric layer 25 and the barrier layer 26, each of which may operate as an etch stop for the process forming the trenches 38. As used herein, the term “selective” in reference to a material removal process (e.g., etching) denotes that, with an appropriate etchant choice, the material removal rate (i.e., etch rate) for the targeted material is greater than the removal rate for at least another material exposed to the material removal process. A discrete etch stop layer is not required in the structure to form the trenches 38, which penetrate through the device layer 12 but not into the interlayer dielectric layer 31 or into device structures 20, 22, 24.

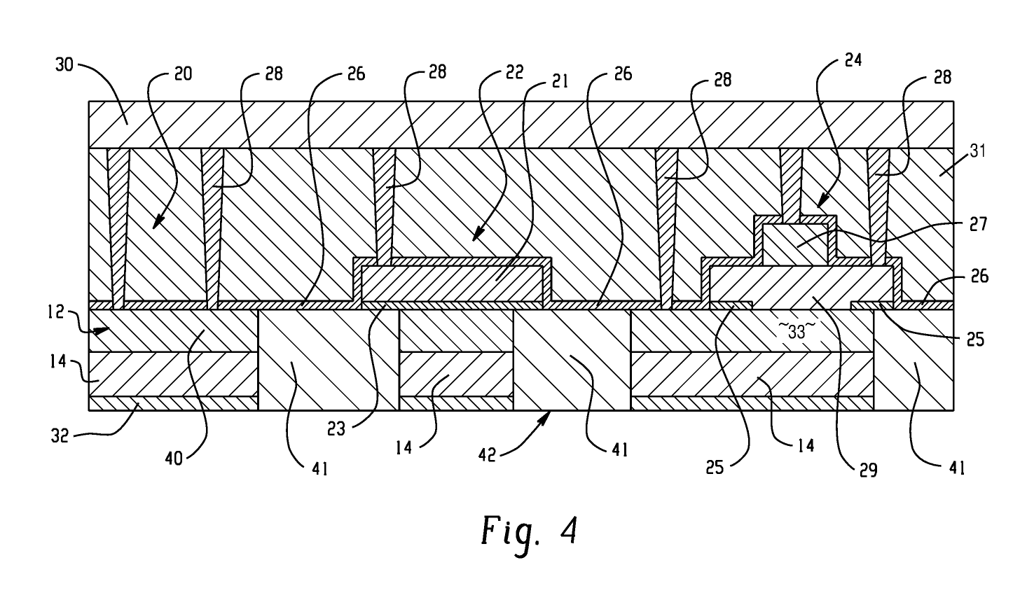

With reference to FIG. 4 in which like reference numerals refer to like features in FIG. 3 and at a subsequent fabrication stage, a dielectric layer 42 is formed that fills the trenches 38 to define trench isolation regions 41. In an embodiment, the dielectric layer 42 may completely fill the trenches 38 to define the trench isolation regions 41. The dielectric layer 42 may be formed by depositing a layer of its constituent solid dielectric material, and planarizing the deposited layer with, for example, CMP to be coplanar with the back side surface 15 of the BOX layer 14. The dielectric layer 42 may be composed of a dielectric material, such as silicon dioxide (SiO₂) deposited by low-temperature CVD, grown by thermal oxidation of silicon (e.g., oxidation at high pressure with steam (HIPOX)), or formed by a combination of these techniques.

In an alternative embodiment, the dielectric material constituting the dielectric layer 42 may be selected to include internal stress that can be transferred to one or more of the device structures 20, 22, 24. For example, the dielectric material may be constituted by silicon nitride (Si₃N₄) deposited by plasma-enhanced chemical vapor deposition (PECVD), either with or without a passivation layer of, for example, silicon dioxide (SiO₂) initially formed on the surfaces surrounding the trenches 38. The deposition conditions (e.g., gas flow rates, chamber pressure, RF power exciting the plasma, etc.) can be selected to form silicon nitride under a state of either compressive stress or tensile stress.

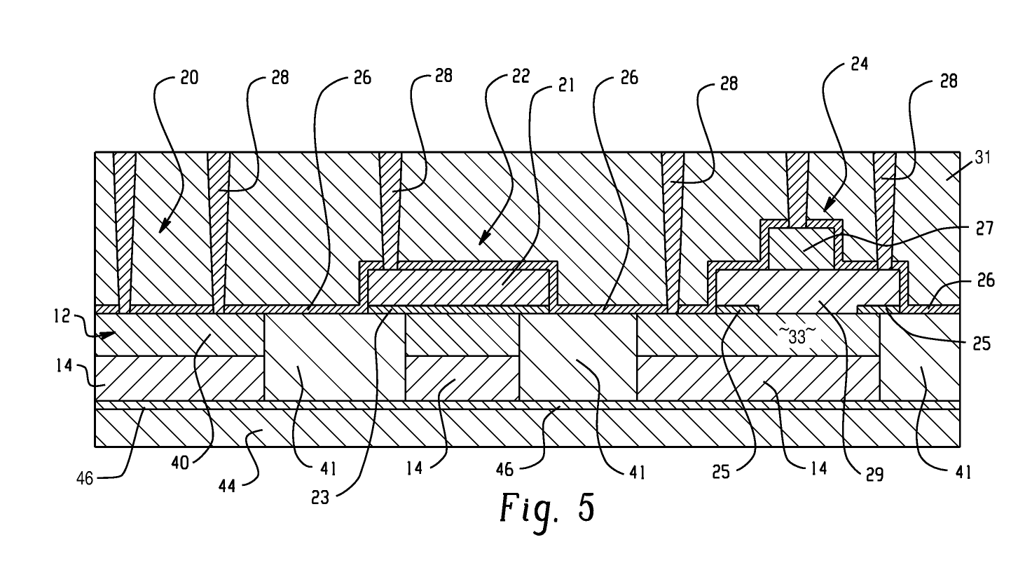

With reference to FIG. 5 in which like reference numerals refer to like features in FIG. 4 and at a subsequent fabrication stage, the dielectric layer 32 may be removed and the dielectric layer 42 may be polished to provide a surface finish that promotes wafer bonding. A carrier wafer 44 that includes a dielectric layer 46 at its top surface may be bonded to the dielectric layer 42 and BOX layer 14. The bonding process may involve a thermal anneal at a sufficient temperature (e.g., 100° C. to 800° C.) and for a duration sufficient to cause bonding between the dielectric layers 42, 46. An external force may apply a mechanical pressure to force the dielectric layers 42, 46 into intimate contact during the thermal anneal so as to promote bonding. In various embodiments, the carrier wafer 44 may be an engineered high-resistance wafer comprised of high-resistance silicon, sapphire, quartz, alumina, etc. that exhibits enhanced performance metrics.

In accordance with the embodiments of the invention, the trench isolation regions 41 are formed from the back side surface 15 in association with a layer transfer process and after the device structures 20, 22, 24 are formed at the front side in an isolation last process. This eliminates the need to form trench isolation regions in a conventional manner before the device structures 20, 22, 24 are formed by front-end-of-line processing and from the front side surface 13 of the semiconductor substrate 10. The trench isolation regions 41 are also formed without the need for a placeholder dielectric layer to operate as an etch stop when the trenches 38 are etched from the back side.

For the device structure 22 that is a field-effect transistor or a switch field-effect transistor with electrode fingers, the layer transfer-based process substantially lowers the cost associated with the formation of conventional trench isolation, eliminates slip-inducing anneals associated with the formation of conventional trench isolation, and eliminate corners at the trench isolation/gate electrode interface. The results may be enhancements in reliability, harmonic distortion, and switch breakdown voltage. In embodiments, the trench isolation regions 41 may incorporate a tunable amount of final stress absent high temperature anneals.

For the device structure 24 that has the construction of a bipolar junction transistor or heterojunction bipolar transistor, the layer transfer-based process eliminates device region to trench isolation edge facets in the base layer, which may reduce the collector-base capacitance (Ccb). The reduction in Ccb improves the performance of the device structure 22 by improving figures of merit, such as cut-off frequency (f_{T}) and maximum oscillation frequency (fₘₐₓ).

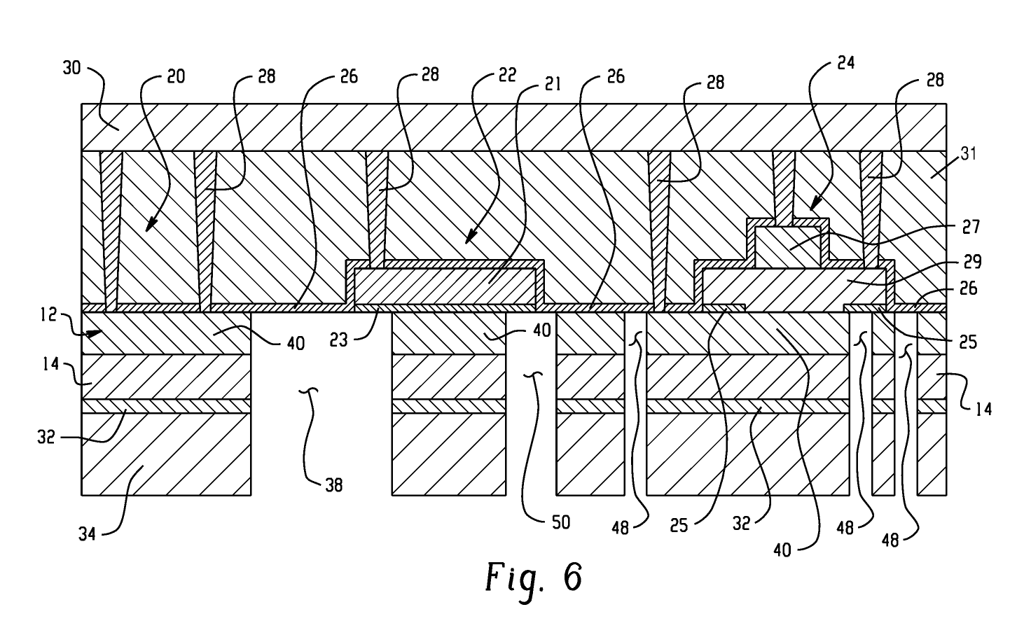

With reference to FIG. 6 in which like reference numerals refer to like features in FIGS. 2, 3 and in accordance with alternative embodiments of the invention, the resist layer 34 may be formed on the dielectric layer 32 and patterned to include openings of different dimensions. The photomask used to expose the resist layer 34 is modified to allow the production of the additional openings, as well as the original openings.

Trench 38 and trenches 48, 50 are formed that extend through the dielectric layer 32, the BOX layer 14, and the device layer 12 at the location of the openings in the resist layer 34. To that end, the patterned resist layer 34 is used as an etch mask for a dry etching process, such as a reactive-ion etching (RIE), that removes unmasked portions of the dielectric layer 32, the BOX layer 14, and the device layer 12 to form the trench 38 and the trenches 48, 50. The etching process may be conducted in a single etching step with a given etch chemistry or in multiple etching steps with different etch chemistries.

Dimensionally, the trenches 48 have a larger height-to-width ratio than the height-to-width ratio of the trenches 38. The trench 50 has a height-to-width ratio that is between the height-to-width ratio of the trenches 48 and the height-to-width ratio of the trench 38. The resist layer 34 is stripped after the trenches 38, 48, 50 are formed.

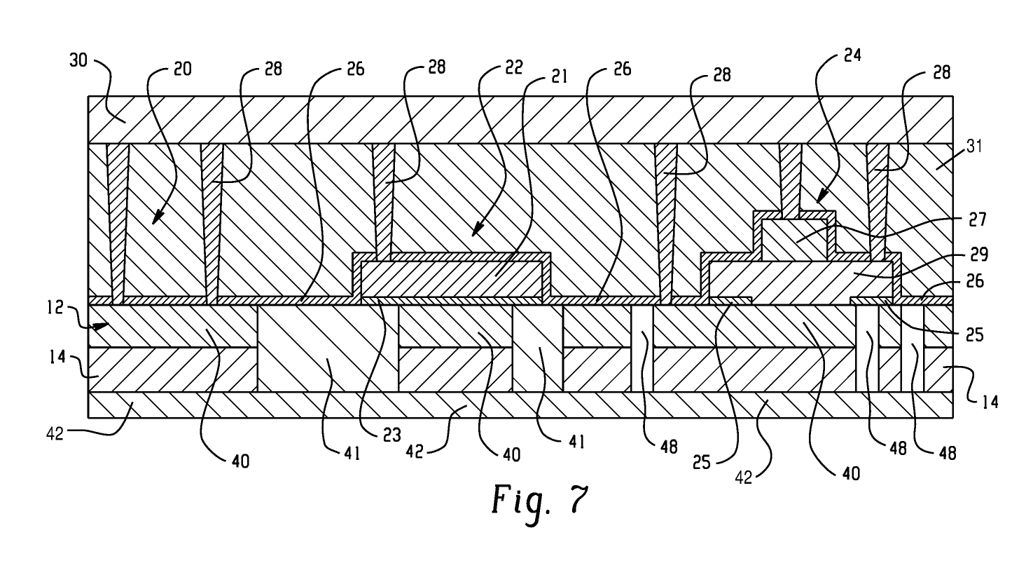

With reference to FIG. 7 in which like reference numerals refer to like features in FIG. 6 and at a subsequent fabrication stage, the dielectric layer 42 is formed that fills the trenches 38 and 50 to define trench isolation regions 41 as described in the context of FIG. 4. The dielectric layer 32 is removed before the dielectric layer 42 is formed. The dielectric layer 42 may be planarized by CMP to remove topography and provide a planar surface that covers the BOX layer 14. The planar surface of the dielectric layer 42 may promote wafer bonding.

Because of their larger height-to-width ratio, the trenches 48 are not filled by the solid dielectric material of the dielectric layer 42, but are instead pinched off to close the trenches 48 at or near their respective entrances. The closed trenches 48 define air gaps that may be characterized by an effective permittivity or dielectric constant of near unity (vacuum permittivity). The closed trenches 48 may be filled by air at or near atmospheric pressure, may be filled by another gas at or near atmospheric pressure, or may contain air or another gas at a sub-atmospheric pressure (e.g., a partial vacuum). The air gaps defined by the closed trenches 48 are partially located in the BOX layer 14 and partially located in the device layer 12.

Processing continues as described in the context of FIG. 5 to bond the dielectric layer 46 on the carrier wafer 44 to the dielectric layer 42.

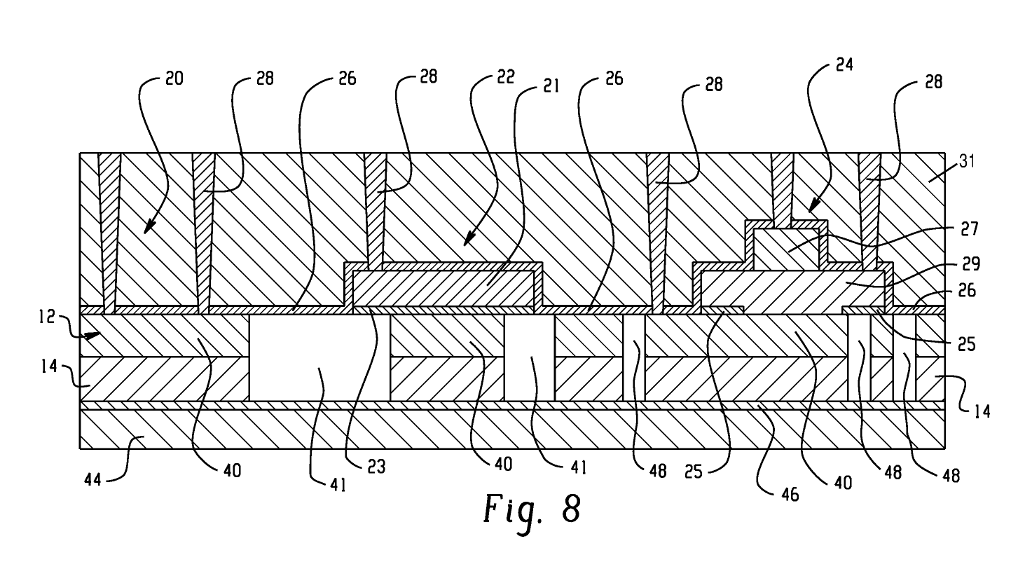

With reference to FIG. 8 in which like reference numerals refer to like features in FIG. 6 and in accordance with alternative embodiments of the invention, the dielectric layer 42 may be omitted and the dielectric layer 46 on the carrier wafer 44 may be directly bonded, as described in the context of FIG. 5, to the BOX layer 14. In addition to the air gaps formed by trenches 48, the trenches 38 and 50 will likewise form air gaps that are not filled by solid dielectric material. Ground rules may be applied to limit the extent of air gap formation and mechanical damage that could result from excessive incorporation of air gaps. In an alternative embodiment, one or more of the trenches 38, 48, 50 may be filled with solid dielectric matter as dummy structures to comply with the ground rules.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, “lateral”, etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction. Terms such as “above” and “below” indicate positioning of elements or structures relative to each other and/or to the top surface of the semiconductor substrate as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method comprising:
obtaining a semiconductor substrate having a buried oxide layer, a device layer on the buried oxide layer, a first surface, and a second surface that is opposite from the first surface of the semiconductor substrate, the device layer and the buried oxide layer arranged between the first surface and the second surface;
forming, by front-end-of-line processing, a transistor on the first surface of the semiconductor substrate;
forming a barrier layer located on the transistor and the first surface of the semiconductor substrate; and
after the transistor and the barrier layer are formed, etching a first trench into the semiconductor substrate from the second surface of the semiconductor substrate through the buried oxide layer and the device layer,
wherein the first trench is used to form an isolation region, and the first trench terminates on a dielectric layer associated with the transistor or on the barrier layer.

2. The method of claim 1 wherein the trench terminates on the dielectric layer of the transistor, the transistor is a field-effect transistor, and the dielectric layer of the transistor is a gate dielectric of the field-effect transistor.

3. The method of claim 1 wherein the trench terminates on the dielectric layer of the transistor, the transistor is a heterojunction bipolar transistor, and the dielectric layer of the transistor is a base dielectric of the heterojunction bipolar transistor.

4. The method of claim 1 wherein the barrier layer is formed by middle-of-line processing, and further comprising:
before the first trench is etched, forming a contact that extends through the barrier layer to be coupled with the transistor.

5. The method of claim 1 further comprising:
after the transistor and the barrier layer are formed, etching a second trench from the second surface of the semiconductor substrate,
wherein the second trench is used to form an air gap.

6. The method of claim 1 further comprising:
depositing a solid dielectric material to fill the first trench.

7. The method of claim 6 further comprising:
after the transistor and the barrier layer are formed, etching a second trench from the second surface of the semiconductor substrate,
wherein the first trench and the second trench are simultaneously etched, the second trench has a higher height-to-width ratio than the first trench, and the dielectric material closes the second trench to form an air gap.

8. The method of claim 1 wherein the front-end-of-line processing excludes formation of trench isolation regions from the first surface of the semiconductor substrate.

9. The method of claim 1 wherein the first trench is etched through the buried oxide layer before being etched through the device layer of the silicon-on-insulator substrate.

10. The method of claim 9 further comprising:
removing a handle wafer of the silicon-on-insulator substrate to reveal the second surface; and
after the first trench is etched, attaching a carrier wafer to the second surface that closes the first trench and defines an air gap.

11. The method of claim 9 further comprising:
removing a handle wafer of the silicon-on-insulator substrate to reveal the second surface; and
after the first trench is etched, depositing a dielectric material on the first surface that closes the first trench and defines an air gap.

12. The method of claim 1 wherein the first trench terminates on the dielectric layer of the transistor.

13. The method of claim 1 wherein the first trench terminates on the barrier layer.

14. The method of claim 1 wherein a material of the dielectric layer of the transistor or the barrier layer functions as an etch stop layer when the first trench is etched.

15. A structure comprising:
a semiconductor substrate having a buried oxide layer, a device layer on the buried oxide layer, a first surface, and a second surface that is opposite from the first surface of the semiconductor substrate, the device layer and the buried oxide layer arranged between the first surface and the second surface;
a transistor on the first surface of the semiconductor substrate, the transistor including a dielectric layer;
a barrier layer on the transistor and the first surface of the semiconductor substrate; and
an isolation region including a trench extending from the second surface of the semiconductor substrate through the buried oxide layer and the device layer to terminate on the dielectric layer of the transistor or on the barrier layer.

16. The structure of claim 15 wherein the trench terminates on the dielectric layer of the transistor, the transistor is a field-effect transistor, and the dielectric layer of the transistor is a gate dielectric of the field-effect transistor.

17. The structure of claim 15 wherein the trench terminates on the dielectric layer of the transistor, the transistor is a heterojunction bipolar transistor, and the dielectric layer of the transistor is a base dielectric of the heterojunction bipolar transistor.

18. The structure of claim 15 the trench terminates on the barrier layer, and further comprising:
a contact that extends through the barrier layer to be coupled with the transistor.

19. The structure of claim 15 wherein the trench is filled with a solid dielectric material.

20. The structure of claim 15 further comprising:
a carrier wafer attached to the second surface of the semiconductor substrate,
wherein the carrier wafer closes the trench to define an air gap.
